(19) United States
(12) Patent Application Publication
(10) Pub. No.: US 2019/0355700 A1
(43) Pub. Date: Nov. 21, 2019

(54) TECHNIQUES FOR WINDOWED SUBSTRATE INTEGRATED CIRCUIT PACKAGES

(71) Applicant: Intel Corporation, Santa Clara, CA (US)

(72) Inventors: Aiping Tan, Shanghai (CN); Bin Liu, Shanghai (CN); Li Deng, Shanghai (CN); Yong She, Songjiang (CN); Zhicheng Ding, Shanghai (CN); Mao Guo, Shanghai (CN)

(21) Appl. No.: 16/474,016

(22) PCT Filed: Dec. 28, 2016
(86) PCT No.: PCT/CN2016/112717

§ 371 Date: Jun. 26, 2019

(51) Int. Cl. H01L 25/065; H01L 25/00; H01L 21/56; H01L 23/31

(52) U.S. Cl. CPC H01L 25/0657; H01L 25/50; H01L 21/56; H01L 23/3128; H01L 2225/06586; H01L 2225/0651; H01L 2225/06558; H01L 2225/06562; H01L 2225/06506

(57) ABSTRACT

Techniques for providing an integrated circuit package that avoids or eliminates x-y area and z-height compared to conventional integrated circuit packages. In certain examples, an example package can utilize a substrate with an opening and bottom side or sidewall terminations to avoid adding addition x-y substrate area or z-axis package height associated with an integrated circuit die of a stack of integrated circuit dies of the package.

### TECHNICAL FIELD

The disclosure herein relates generally to integrated circuits and more particularly to techniques for bonding integrated circuit to windowed structures, such as windowed substrates

### BACKGROUND

Stacking integrated circuit dies and attaching to a substrate has become a popular configuration for system-in-package products. Some limit for such configurations have been realized, however. For example, connections between the top die of the stack and the substrate can require relatively long bond wires that can increase the risk of movement of the bond wire, bond wire sagging and undesired contact or shorting with other electrical features of the system. Also, adding an additional die to the stack results in increased x-y surface area of the substrate to allow for wire bonding and increased z-axis height of the package.

### BRIEF DESCRIPTION OF THE DRAWINGS

In the drawings, which are not necessarily drawn to scale, like numerals may describe similar components in different views. Like numerals having different letter suffixes may represent different instances of similar components. Some embodiments are illustrated by way of example, and not limitation, in the figures of the accompanying drawings in which:

FIG. 1 illustrates generally an example package that includes a stack of integrated circuit dies connected to a windowed substrate.

FIG. 2 illustrates generally an example package that includes a stack of integrated circuit dies connected to a windowed substrate.

FIG. 3 illustrates generally an example package that includes a stack of integrated circuit dies connected to a windowed substrate.

FIG. 4 illustrates generally an example method for fabricating an example package.

FIG. 5 illustrates a system level diagram, depicting an example of an electronic device (e.g., system) including a windowed substrate as described in the present disclosure.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

The present inventors have recognized techniques for integrating an integrated circuit of a stack of integrated circuits with the stack and with a substrate without adding height (z direction) or cross-dimensional area (x-y) to the overall package and avoiding abnormally long electrical bonding wires for electrically connecting the integrated circuit to the substrate.

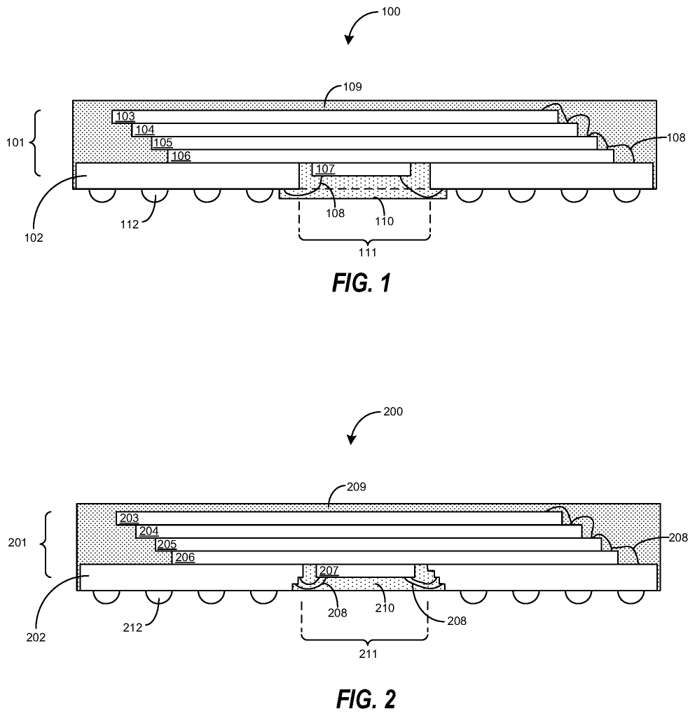

FIG. 1 illustrates generally an example package 100 that includes a stack 101 of integrated circuit dies 103-107 connected to a substrate 102 or printed circuit board (PCB). In certain examples, the package 100 can include the stack 101, the substrate 102, bonding wires 108 and package material 109, 110. The package material 109, 110 can enclose and protect the circuits and the electrical and mechanical connections. The substrate 102 can include solder balls 112, possibly arranged in an array such as a grid array, to connect the package to other circuits or devices.

The stack 101 can be mounted on the substrate 102, and the substrate 102 can include an opening 111 or a window such that when the stack 101 is mounted to the substrate 102, one of the integrated circuits of the stack, the bottom IC 107, can occupy the opening area of the substrate 102 and avoid adding either vertical dimension to the overall package 100 as well as avoiding additional x-y area to the overall package 100. In certain examples, the substrate 102 can include electrical terminations or pads for the stack 101 on a top major surface of the substrate 102. In certain examples, the stack is attached to the substrate one integrated circuit die at a time. For example, a first integrated circuit die 106 can be mounted to the substrate 102 over the opening 111 and then wire bonded to the substrate 102 using wire bond wires 108. A second integrated circuit die 105 can be mounted on the first integrated circuit die 106 and wire bonded to the substrate 102. The process for the second integrated circuit 105 die can be repeated for any additional integrated circuit dies 103, 104 of the stack 113. In some examples, additional x-y area of the substrate 102 can be avoided or saved by having bonding wires 108 for the bottom IC 107 attach to terminations or pads located on the underside or bottom major surface of the substrate 102.

In certain examples, the package may represent an embedded multi-media controller (eMMC) or system-in-package (SiP), such as an SiP that includes an application specific integrated circuit (ASIC) and a stack of memory.

FIG. 2 illustrates generally an example package 200 that includes a stack 201 of integrated circuit dies 203-207 connected to a substrate 202. In certain examples, the package 200 can include the stack 201, the substrate 202, bonding wires 208 and package material 209, 210. The package material 209, 210 can enclose and protect the circuits and the electrical and mechanical connections. The substrate 202 can include solder balls 212, possibly arranged in an array such as a grid array, to connect the package to other circuits or devices.

The stack 201 can be mounted on the substrate 202, and the substrate 202 can include an opening 211 or a window such that when the stack 201 is mounted to the substrate 202, one of the integrated circuits of the stack, the bottom IC 207, can occupy the opening area of the substrate 202 and avoid adding either vertical dimension to the overall package 200 as well as avoiding additional x-y area to the overall package 200. In certain examples, the substrate 202 can include electrical terminations for the stack 201 on a top major surface of the substrate 202. In some examples, additional x-y area of the substrate 202 can be avoided or saved by having bonding wire 208 for the bottom IC 107 attach to terminations or pads located on sidewalls that define the opening 211 of the substrate 202. In certain examples, the sidewalls of the substrate can be stepped, and termination can be located on a landing of each step. In some examples, the sidewall can include multiple steps and landings such that a higher density of terminations can be provided for electrically connecting with the bottom IC 207.

In certain examples, the package 200 may represent an embedded multi-media controller (eMMC) or system-in-package (SiP), such as an SiP that includes an application specific integrated circuit (ASIC) and a stack of memory.

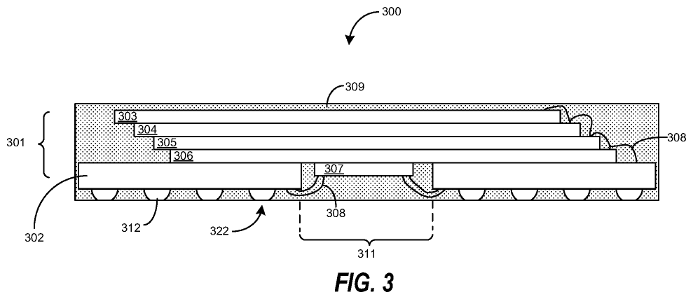

FIG. 3 illustrates generally an example package 300 that includes a stack 301 of integrated circuit dies 303-307 connected to a substrate 302. In certain examples, the package 300 can include the stack 301, the substrate 302, bonding wires 308 and package material 309. The package material 309 can enclose and protect the circuits and the electrical and mechanical connections. The substrate 302 can include termination connections 312, possibly arranged in an array such as a grid array, to connect the package to other circuits or devices.

The stack 301 can be mounted on the substrate 302, and the substrate 302 can include an opening 311 or a window such that when the stack 301 is mounted to the substrate 302, one of the integrated circuits of the stack, the bottom IC 307, can occupy the opening area of the substrate 302 and avoid adding either vertical dimension to the overall package 300 as well as avoiding additional x-y area to the overall package 300. In certain examples, the substrate 302 can include electrical terminations for the stack 301. In some examples, additional x-y area of the substrate 302 can be avoided or saved by having bonding wire 308 for the bottom IC 307 attach to termination located on the underside of the substrate 302. In certain examples, the package material 309 can extend to fill recesses of the opening 311. Exposed surfaces 322 of the termination connections 312 can be flush with the exterior surface of the package material 309 to form, for example, a land grid array of terminations.

In certain examples, the package 300 may represent an embedded multi-media controller (eMMC) or system-in-package (SiP), such as an SiP that includes an application specific integrated circuit (ASIC) and a stack of memory.

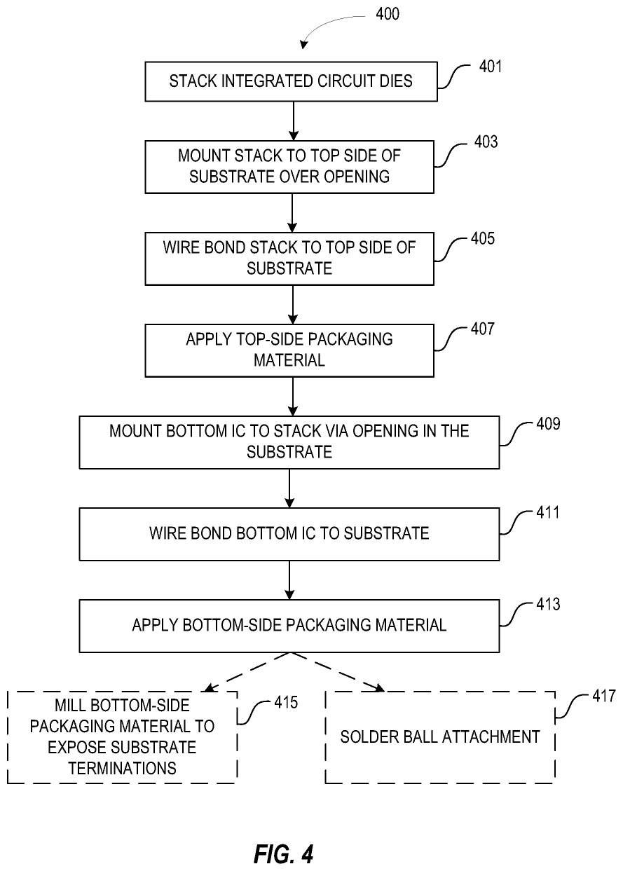

FIG. 4 illustrates generally an example method for fabricating an example package. At 401, integrated circuit dies can be mounted to each other to form a stack of integrated circuit dies. In some examples, the stack can include a stack of memory dies. At 403, the stack can be mounted to a top-side of a substrate. The substrate can include an opening and the stack can be mounted to the substrate over the opening. At 405, the stack can be wire bonded to the top side of the substrate. At 407, packaging material can be applied to the top of the substrate to cover the stack and top-side terminations. In certain examples, the package material can be molded to form the top-side of the package.

At 409, a bottom integrated circuit (IC) can be attached to the bottom of the stack through the opening in the substrate. In certain examples, the opening can be sized and shaped to accommodate the bottom integrated circuit. For example, the opening can be based on the size and shape of the exterior of the bottom IC. In some examples, upon mounting the bottom IC, the bottom IC is positioned within the opening of the substrate. In certain examples, the substrate with the mounted stack can be flipped to allow better access to the opening for attaching or mounting the bottom IC as well as for other processing associated with the bottom side of the substrate. In some examples, the bottom IC can be an ASIC. In some examples, the bottom IC can include a memory interface circuit. At 411, wire bonds can be connected between the bottom IC and the substrate. In certain examples, the wire bonds can be terminated on a bottom surface of the substrate. In some examples, the wire bonds can be terminated to a stepped surface of a sidewall of the opening in the substrate. At 413, package material can be applied to enclose and protect the bottom IC and wire bonds. In some examples, the package material can also cover the bottom side of the substrate. At 415, the bottom-side package material can optionally be milled to expose termination surfaces of the substrate such as a land grid array (LGA). At 417, in certain examples, a substrate may not include bottom side terminations, therefore, solder balls, or some other type of bottom side termination, can be attached to the bottom of the substrate.

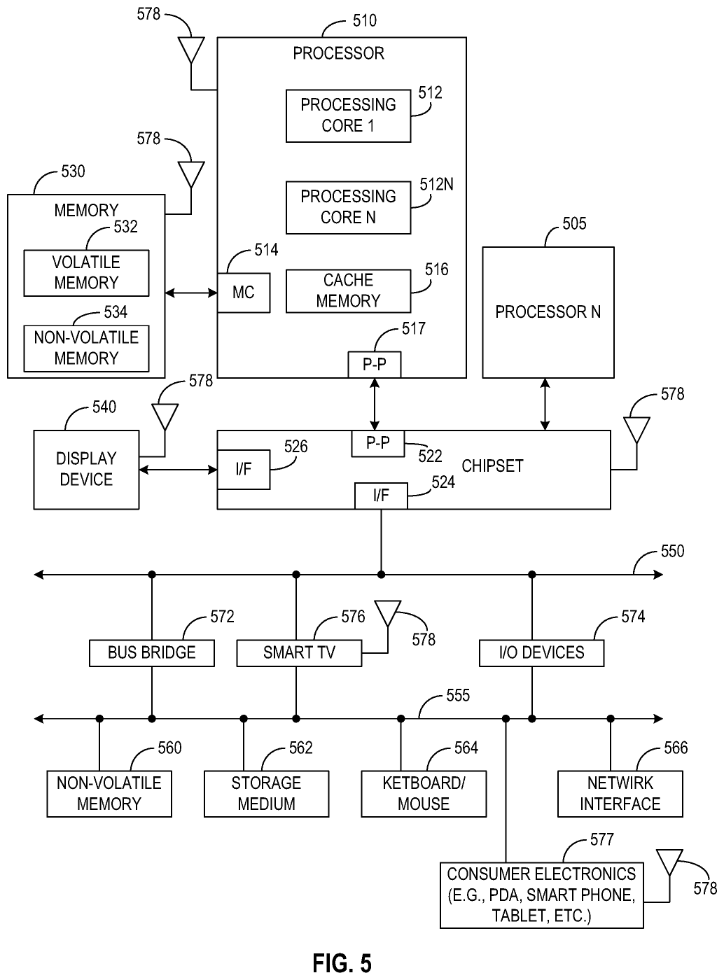

FIG. 5 illustrates a system level diagram, depicting an example of an electronic device (e.g., system) including integrated circuits with a smart accelerometer cantilever as described in the present disclosure. FIG. 5 is included to show an example of a higher level device application for integrated circuits with a smart accelerometer cantilever. In one embodiment, system 500 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 500 is a system on a chip (SOC) system.

In one embodiment, processor 510 has one or more processor cores 512 and 512N, where 512N represents the Nth processor core inside processor 510 where N is a positive integer. In one embodiment, system 500 includes multiple processors including 510 and 505, where processor 505 has logic similar or identical to the logic of processor 510. In some embodiments, processing core 512 includes, but is not limited to, pre-fetch logic to fetch instructions, decode logic to decode the instructions, execution logic to execute instructions and the like. In some embodiments, processor 510 has a cache memory 516 to cache instructions and/or data for system 500. Cache memory 516 may be organized into a hierarchal structure including one or more levels of cache memory.

In some embodiments, processor 510 includes a memory controller 514, which is operable to perform functions that enable the processor 510 to access and communicate with memory 530 that includes a volatile memory 532 and/or a non-volatile memory 534. In some embodiments, processor 510 is coupled with memory 530 and chipset 520. Processor 510 may also be coupled to a wireless antenna 578 to communicate with any device configured to transmit and/or receive wireless signals. In one embodiment, an interface for wireless antenna 578 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 532 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 534 includes, but is not limited to, flash memory, phase change memory (PCM), read-only memory (ROM), electrically erasable programmable read-only memory (EEPROM), or any other type of non-volatile memory device.

Memory 530 stores information and instructions to be executed by processor 510. In one embodiment, memory 530 may also store temporary variables or other intermediate information while processor 510 is executing instructions. In the illustrated embodiment, chipset 520 connects with processor 510 via Point-to-Point (PtP or P-P) interfaces 517 and 522. Chipset 520 enables processor 510 to connect to other elements in system 500. In some embodiments of the example system, interfaces 517 and 522 operate in accordance with a PtP communication protocol such as the Intel® QuickPath Interconnect (QPI) or the like. In other embodiments, a different interconnect may be used.

In some embodiments, chipset 520 is operable to communicate with processor 510, 505N, display device 540, and other devices, including a bus bridge 572, a smart TV 576, I/O devices 574, nonvolatile memory 560, a storage medium (such as one or more mass storage devices) 562, a keyboard/mouse 564, a network interface 566, and various forms of consumer electronics 577 (such as a PDA, smart phone, tablet etc.), etc. In one embodiment, chipset 520 couples with these devices through an interface 524. Chipset 520 may also be coupled to a wireless antenna 578 to communicate with any device configured to transmit and/or receive wireless signals.

Chipset 520 connects to display device 540 via interface 526. Display 540 may be, for example, a liquid crystal display (LCD), a plasma display, cathode ray tube (CRT) display, or any other form of visual display device. In some embodiments of the example system, processor 510 and chipset 520 are merged into a single SOC. In addition, chipset 520 connects to one or more buses 550 and 555 that interconnect various system elements, such as I/O devices 574, nonvolatile memory 560, storage medium 562, a keyboard/mouse 564, and network interface 566. Buses 550 and 555 may be interconnected together via a bus bridge 572.

In one embodiment, mass storage device 562 includes, but is not limited to, a solid state drive, a hard disk drive, a universal serial bus flash memory drive, or any other form of computer data storage medium. In one embodiment, network interface 566 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 5 are depicted as separate blocks within the system 500, the functions performed by some of these blocks may be integrated within a single semiconductor circuit or may be implemented using two or more separate integrated circuits. For example, although cache memory 516 is depicted as a separate block within processor 510, cache memory 516 (or selected aspects of 516) can be incorporated into processor core 512.

### Additional Examples and Notes

In Example 1, an integrated circuit (IC) package can include a circuit substrate, a first integrated circuit die mounted to the circuit substrate, a second integrated circuit die mounted to the first integrated circuit die, wherein the substrate includes an opening, and wherein the second integrated circuit is positioned within the opening when the first integrated circuit die is mounted to the substrate.

In Example 2, the first integrated circuit of Example 1 optionally includes a memory integrated circuit.

In Example 3, the second integrated circuit of any one of Examples 1-2 optionally includes a memory interface circuit.

In Example 4, the second integrated circuit of any one of Examples 1-3 optionally includes an application specific integrated circuit (ASIC).

In Example 5, the first integrated circuit of any one of Examples 1-4 optionally is mounted to a first major surface of the substrate over the opening.

In Example 6, the IC package of any one of Examples 1-5 optionally includes first bond wires coupled to the first integrated circuit and to first landing pads of the first major surface of the substrate.

In Example 7, the IC package of any one of Examples 1-6 optionally includes second bond wires coupled to the second integrated circuit and to second landings of a second major surface of the substrate, the second major surface located opposite the first major surface.

In Example 8, the substrate of any one of Examples 1-7 optionally includes stepped sidewalls configured define the opening.

In Example 9, the IC package of any one of Examples 1-8 optionally includes second bond wires coupled to the second integrated circuit and to second landing pads of a first step of the stepped sidewalls.

In Example 10, the IC package of any one of Examples 1-9 optionally includes third bond wires coupled to the second integrated circuit and to third landing pads of a second step of the stepped sidewalls.

In Example 11, a method can includes connecting a plurality of integrated circuit (IC) dies into a stack, mounting the stack to a top side of a substrate over an opening of the substrate, wire bonding the stack to terminations located on the top side of the substrate, and mounting a bottom IC die to the stack via the opening.

In Example 12, the connecting the plurality of IC dies into a stack of any one of Examples 1-11 optionally includes connecting the plurality of memory dies into a stack.

In Example 13, the mounting a bottom IC die to the stack via the opening of any one of Examples 1-12 optionally includes mounting a memory controller interface circuit die to the stack via the opening.

In Example 14, the mounting a bottom IC die to the stack via the opening of any one of Examples 1-13 optionally includes mounting an application specific integrated circuit (ASIC) to the stack via the opening.

In Example 15, the method of any one of Examples 1-14 optionally includes wire bonding the bottom IC to terminations located on a surface of the substrate other than the top side of the substrate.

In Example 16, the method of any one of Examples 1-15 optionally includes wire bonding the bottom IC to terminations located on a bottom side of the substrate.

In Example 17, the opening of any one of Examples 1-16 optionally includes stepped sidewalls. In certain examples, the wire bonding the bottom IC of any one of Examples 1-16 optionally includes wire bonding the bottom IC to terminations located on a first step of the stepped sidewalls of the opening.

In Example 18, the wire bonding the bottom IC of any one of Examples 1-17 optionally includes wire bonding the bottom IC to terminations located on a second step of the stepped sidewalls of the opening.

In Example 19, the method of any one of Examples 1-18 optionally includes applying package material to protect the stack, wire bonds and bottom IC.

In Example 20, the method of any one of Examples 1-19 optionally includes milling the package material to expose external substrate terminations.

In Example 21, an electronic device can include a substrate, a processor circuit, a first integrated circuit die mounted to the substrate, a second integrated circuit die mounted to the first integrated circuit die, at least one of a display device and a network interface operably coupled to the processor circuit via the substrate, wherein the substrate includes an opening, and wherein the second integrated circuit is positioned within the opening when the first integrated circuit die is mounted to the substrate.

In Example 22, the first integrated circuit of any one or more of Example 1-21 optionally includes a memory circuit.

In Example 23, the second integrated circuit of any one or more of Example 1-22 optionally includes the processor circuit.

In Example 24, the processor circuit of any one or more of Example 1-21 optionally is an application specific integrated circuit (ASIC).

In Example 25, the substrate, the processor, the first integrated circuit, and the second integrated circuit of any one or more of Example 1-24 optionally are stacked to form a system-in-package (SiP) device.

In Example 26, the first integrated circuit of any one or more of Example 1-25 optionally is mounted to a first major surface of the substrate over the opening.

In Example 27, the electronic device of any one or more of Example 1-26 optionally includes first bond wires coupled to the first integrated circuit and to first landing pads of the first major surface of the substrate.

In Example 28, the electronic device of any one or more of Example 1-21 optionally includes second bond wires coupled to the second integrated circuit and to second landings of a second major surface of the substrate, the second major surface located opposite the first major surface.

In Example 29, the substrate of any one or more of Example 1-28 optionally includes stepped sidewalls configured define the opening.

In Example 30, the electronic device of any one or more of Example 1-29 optionally includes second bond wires coupled to the second integrated circuit and to second landing pads of a first step of the stepped sidewalls.

In Example 31, the electronic device of any one or more of Example 1-30 optionally third bond wires coupled to the second integrated circuit and to third landing pads of a second step of the stepped sidewalls.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are legally entitled.

1. An integrated circuit (IC) package comprising:
a substrate;
a first integrated circuit die mounted to the substrate;
a second integrated circuit die mounted to the first integrated circuit die and electrically connected directly to the first integrated circuit die;
wherein the substrate includes an opening; and
wherein the second integrated circuit is positioned within the opening when the first integrated circuit die is mounted to the substrate.

2. The IC package of claim 1, wherein the first integrated circuit includes a memory integrated circuit.

3. The IC package of claim 2, wherein the second integrated circuit includes a memory interface circuit.

4. The IC package of claim 2, wherein the second integrated circuit includes an application specific integrated circuit (ASIC).

5. The IC package of claim 1, wherein the first integrated circuit is mounted to a first major surface of the substrate over the opening.

6. The IC package of claim 5, including first bond wires coupled to the first integrated circuit and to first landing pads of the first major surface of the substrate.

7. The IC package of claim 6, including second bond wires coupled to the second integrated circuit and to second landings of a second major surface of the substrate, the second major surface located opposite the first major surface.

8. The IC package of claim 7, wherein the substrate includes stepped sidewalls configured define the opening.

9. The IC package of claim 8, including second bond wires coupled to the second integrated circuit and to second landing pads of a first step of the stepped sidewalls.

10. The IC package of claim 9, including third bond wires coupled to the second integrated circuit and to third landing pads of a second step of the stepped sidewalls.

11. A method comprising:
connecting a plurality of integrated circuit (IC) dies into a stack;
mounting the stack to a top side of a substrate over an opening of the substrate;
wire bonding the stack to terminations located on the top side of the substrate; and
mounting a bottom IC die to the stack via the opening.

12. The method of claim 11, wherein the connecting the plurality of IC dies into a stack includes connecting the plurality of memory dies into a stack.

13. The method of claim 12, wherein the mounting a bottom IC die to the stack via the opening includes mounting a memory controller interface circuit die to the stack via the opening.

14. The method of claim 12, wherein the mounting a bottom IC die to the stack via the opening includes mounting an application specific integrated circuit (ASIC) to the stack via the opening.

15. The method of claim 11, including wire bonding the bottom IC to terminations located on a surface of the substrate other than the top side of the substrate.

16. The method of claim 11, including wire bonding the bottom IC to terminations located on a bottom side of the substrate.

17. The method claim 15, wherein the opening includes stepped sidewalls; and
wherein the wire bonding the bottom IC includes wire bonding the bottom IC to terminations located on a first step of the stepped sidewalls of the opening.

18. The method of claim 17, wherein the wire bonding the bottom IC includes wire bonding the bottom IC to terminations located on a second step of the stepped sidewalls of the opening.

19. The method of claim 15 including applying package material to protect the stack, wire bonds and bottom IC.

20. The method of claim 19, including milling the package material to expose external substrate terminations.

21. An electronic device, comprising,
a substrate;
a processor circuit;
a first integrated circuit die mounted to the substrate;
a second integrated circuit die mounted to the first integrated circuit die;
at least one of a display device and a network interface operably coupled to the processor circuit via the substrate;
wherein the substrate includes an opening; and
wherein the second integrated circuit is positioned within the opening when the first integrated circuit die is mounted to the substrate.

22. The electronic device of claim 21, wherein the first integrated circuit includes a memory circuit.

23. The electronic device of claim 22, wherein the second integrated circuit includes the processor circuit.

24. The electronic device of claim 23, wherein the processor circuit is an application specific integrated circuit.

25. The electronic device of claim 21, wherein the substrate, the processor, the first integrated circuit, and the second integrated circuit are stacked to form a system-in-package (SiP) device.
